(19) United States
(12) Patent Application Publication
(10) Pub. No.: US 2026/0213478 A1
(43) Pub. Date: Jul. 23, 2026

(54) ELECTRICAL CONNECTION UNIT

(71) Applicant: YAZAKI CORPORATION, Tokyo (JP)

(72) Inventor: Thanh Cong Pham, Kakegawa-shi (JP)

(21) Appl. No.: 19/452,173

(22) Filed: Jan. 16, 2026

(30) Foreign Application Priority Data
Jan. 23, 2025 (JP) 2025-009687

(51) Int. Cl. H01R 25/16; H01R 13/512

(52) U.S. Cl. CPC H01R 25/162; H01R 13/512

(57) ABSTRACT

The electrical connection unit including a first routing member that has a first end portion electrically connected to a first external unit and a first extension portion, a first holding member that holds the first extension portion, a second routing member that has a second end portion electrically connected to the first external unit or a second external unit and a second extension portion and disposed at a position different from the first extension portion in a first direction when a thickness direction of the second end portion is the first direction, and a second holding member that is formed separately from the first holding member and holds the second extension portion. The first holding member has a holding portion that holds the first end portion of the first routing member and the second end portion of the second routing member.

### BACKGROUND OF THE INVENTION

### Field of the Invention

Embodiments of the present invention relate to an electrical connection unit.

Priority is claimed on Japanese Patent Application No. 2025-009687 filed in Japan on Jan. 23, 2025, the content of which is incorporated herein by reference.

### Description of Related Art

In the electrical connection unit, it is known that electronic components such as relays and resistors are mounted on a mounting surface of a housing. A conductive member (routing member) such as a bus bar is electrically connected to the electronic component.

### PRIOR ART DOCUMENT

### Patent document

Patent Document 1: Japanese Unexamined Patent Application, First Publication No. 2018-113184

### SUMMARY OF THE INVENTION

Incidentally, in order to realize high-density mounting, a plurality of routing members may be mounted in one electrical connection unit. In addition, some routing members have an end portion electrically connected to an external unit, but it has been a problem that the distance between end portions for external connection of the routing members becomes unstable.

One embodiment provides an electrical connection unit capable of stabilizing the distance between end portions for external connection of routing members.

An electrical connection unit of one embodiment is an on-vehicle electrical connection unit including a first routing member that has a first end portion electrically connected to a first external unit and a first extension portion extending from the first end portion, a first holding member that holds at least the first extension portion of the first routing member, a second routing member that has a second end portion electrically connected to the first external unit or a second external unit and a second extension portion extending from the second end portion and disposed at a position different from the first extension portion in a first direction when a thickness direction of the second end portion is the first direction, and a second holding member that is formed separately from the first holding member and holds at least the second extension portion of the second routing member, wherein the first holding member has a holding portion that holds the first end portion of the first routing member and the second end portion of the second routing member.

According to one embodiment, it is possible to stabilize the distance between end portions for external connection of routing members.

### BRIEF DESCRIPTION OF THE DRAWINGS

FIG. 1 is a perspective view illustrating an electrical connection unit according to an embodiment.

FIG. 2 is an exploded perspective view illustrating a metal cover and a first structure according to the embodiment.

FIG. 3 is an exploded perspective view illustrating the first structure, a relay bus bar, and a part of an external connection bus bar according to the embodiment.

FIG. 4 is an exploded perspective view illustrating the electrical connection unit according to the embodiment.

FIG. 5 is a plan view illustrating the electrical connection unit according to an embodiment.

FIG. 6 is a plan view illustrating the electrical connection unit according to an embodiment as seen through a second cover.

FIG. 7 is a perspective view illustrating a holding portion and a peripheral structure of the holding portion according to the embodiment.

FIG. 8 is a plan view illustrating the holding portion and the peripheral structure of the holding portion according to the embodiment.

FIG. 9 is a plan view illustrating a first holding member according to the embodiment.

FIG. 10 is a cross-sectional view taken along line F10-F10 of the structure illustrated in FIG. 7.

FIG. 11 is a cross-sectional view taken along line F11-F11 of the structure illustrated in FIG. 7.

FIG. 12 is a plan view illustrating a holding portion and a peripheral structure of the holding portion according to a modification example of the embodiment.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. The constitution to be described below does not limit the scope of the embodiment.

In the present disclosure, terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). The term “cover” is not limited to a case where the entire target is covered, and may include a case where only a part of the target is covered. The term “facing” indicates that virtual projection images of two target objects overlap each other when viewed in a specific direction. That is, the term “facing” is not limited to a case where two target objects directly face each other, and may include a case where two target objects face each other in a state in which another member exists between the two target objects. The term “orthogonal”, or “the same” may include “substantially orthogonal”, or “substantially the same”, respectively. The term “sheet-shaped” or “sheet” is not limited to a member having a thickness of 1 mm or more, and may be a member (so-called a film) having a thickness of less than 1 mm.

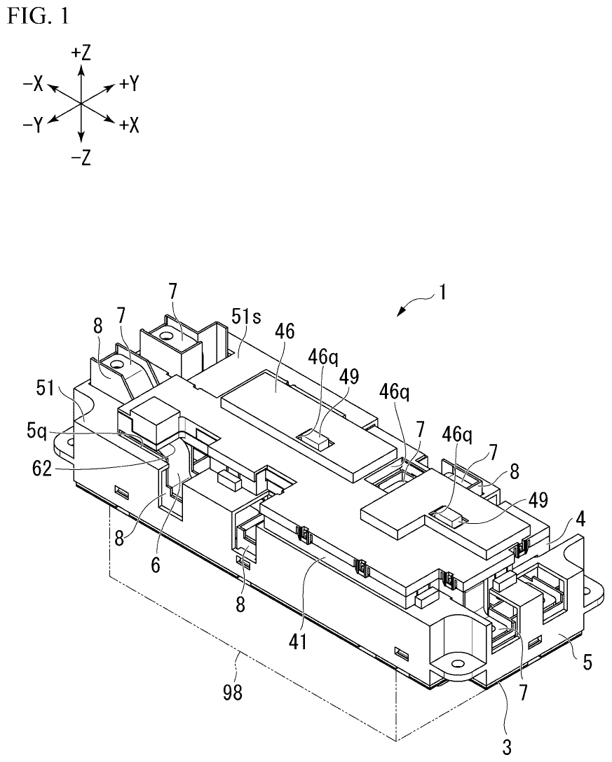

In the present disclosure, a +X direction, a −X direction, a +Y direction, a −Y direction, a +Z direction, and a −Z direction are defined as follows. As illustrated in FIG. 1, an X direction is one direction in a plane along a support surface 51s of a support portion 51 which will be described below. The +X direction is one direction of the X direction. The −X direction is a direction opposite to the +X direction. Hereinafter, the +X direction and the −X direction are simply referred to as the “X direction” in a case where they are not distinguished from each other. A Y direction is a direction intersecting (for example, orthogonal to) the X direction in a plane along the support surface 51s of the support portion 51 which will be described below. The +Y direction is one direction of the Y direction. The −Y direction is a direction opposite to the +Y direction. Hereinafter, the +Y direction and the −Y direction are simply referred to as the “Y direction” in a case where they are not distinguished from each other. The +Z direction and the −Z direction are directions intersecting (for example, orthogonal to) the X direction and the Y direction. The +Z direction is a direction in which the support surface 51s of the support portion 51 which will be described below faces. The −Z direction is a direction opposite to the +Z direction. Hereinafter, in a case where the +Z direction and the −Z direction are not distinguished, the directions will be simply referred to as a “Z direction”. The Z direction is an example of a “first direction”. The Y direction is an example of a “second direction”. Also, the X direction may be referred to as a “third direction”. Also, a +Y direction side is an example of a “first side in the second direction”, and a −Y direction side is an example of a “second side in the second direction”.

Hereinafter, in a case where the X direction and the Y direction are not distinguished, the directions may be referred to as a “horizontal direction”. Hereinafter, the Z direction may be referred to as a “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### EMBODIMENTS

### 1. Constitution of Electrical Connection Unit

The electrical connection unit 1 (The on-vehicle electrical connection unit 1) is provided on the vehicle. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 is connected to a plurality of external devices present outside. The electrical connection unit 1 mediates connection between the plurality of external devices (hereinafter also referred to as a “product”). For example, the external devices may include a battery pack, a load, a charger, and the like. The battery pack is mounted on a vehicle. The load is a device including an inverter or the like for driving a motor of a vehicle driven by using power stored in the battery pack. The charger is a device for supplying power for charging the battery pack. The electrical connection unit 1 may be referred to as an “electrical connection box” or a “junction box”, for example. However, the electrical connection unit 1 is not limited to a box-shaped device.

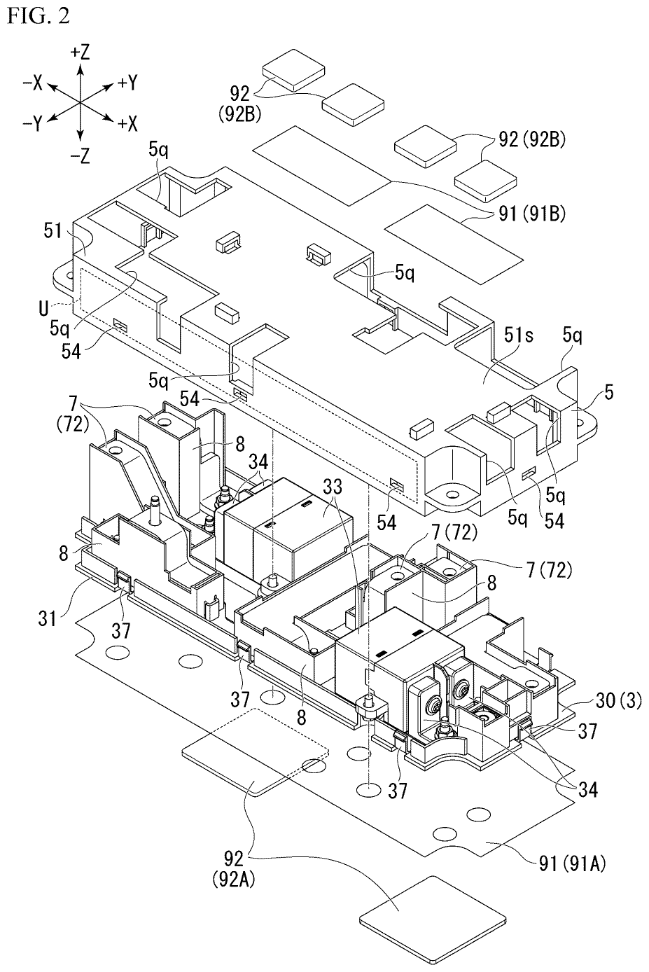

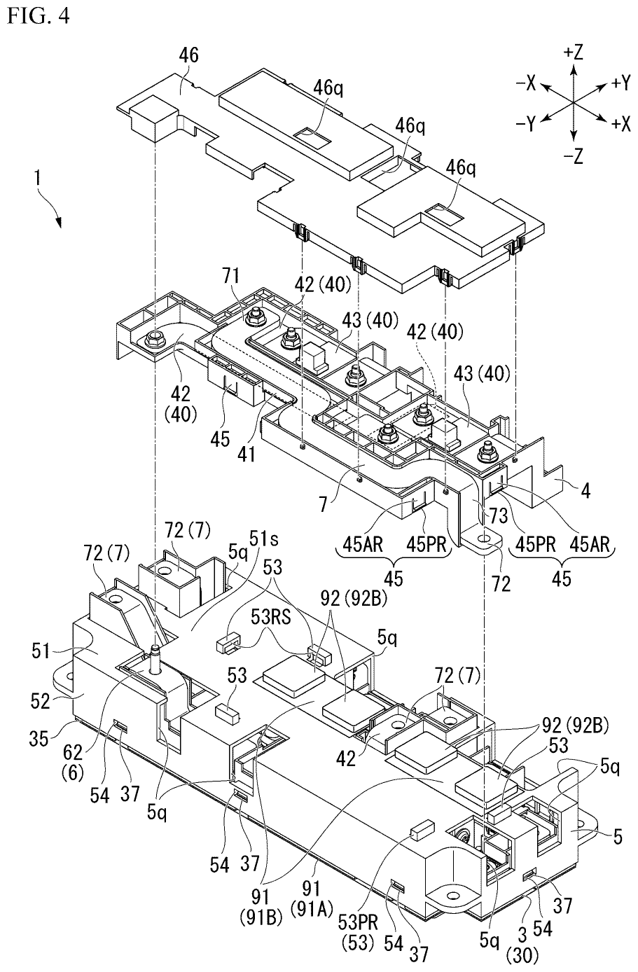

The electrical connection unit 1 includes a first structure 3, a second structure 4, a metal base 5, a relay bus bar 6, a plurality of external connection bus bars 7, and a plurality of auxiliary base members 8. The electrical connection unit 1 further includes an insulating sheet 91 and a heat transfer member 92 (see FIGS. 2 and 4). The second structure 4 is supported by the metal base 5. The second structure 4 is stacked on the first structure 3 with the metal base 5 interposed therebetween in the +Z direction. By this stacking, the electrical connection unit 1 has at least a two-story hierarchical structure. For example, the electrical connection unit 1 may be disposed in contact with a cooling surface of an external cooler 98 from the −Z side. The external cooler 98 may be, for example, a water jacket.

### 2. Constitution of First Structure

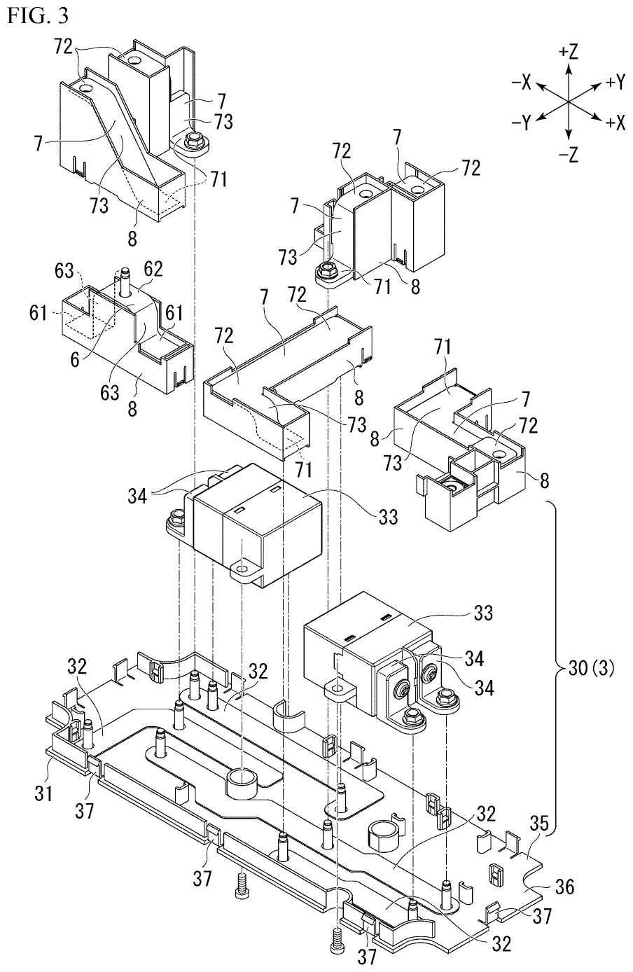

As illustrated in FIG. 2, the first structure 3 includes a first circuit 30. The first circuit 30 includes a routing board 31, a plurality of first electronic components 33, and a plurality of connection components 34. As illustrated in FIG. 3, the routing board 31 includes a plurality of bus bars 32 and a base plate 35.

### (First Electronic Component)

Each first electronic component 33 is an important component for exerting a function of mediating connection between a plurality of external devices among the electronic components included in the electrical connection unit 1. Each first electronic component 33 may be, for example, an electronic component required for the electrical connection unit 1 in common for different products to which the electrical connection unit 1 is applied. The plurality of first electronic components 33 may include, for example, a relay (for example, a mechanical relay or a semiconductor relay). The plurality of first electronic components 33 may include, for example, a relay capable of switching between conduction and disconnection of the largest current among relays mounted on the electrical connection unit 1. Each first electronic component 33 is electrically connected to at least one bus bar 32 among the plurality of bus bars 32. Each first electronic component 33 may be electrically connected to the bus bar 32 via a pair of connection components 34, for example.

### (Routing Board)

The routing board 31 is a board for forming at least a part of an energization path connected to the first electronic component 33. In the present disclosure, the “routing board” indicates a board-type routing structure. The “board-type” indicates a plate shape along one plane when viewed as a whole regardless of a fine shape. In the present disclosure, the “plate shape” is not limited to a completely flat shape, and may include a case where a fixing structure, a rib, or the like protruding in the Z direction is partially present. In the present embodiment, the routing board 31 has a plate shape formed in the X direction and the Y direction. The routing board 31 includes at least one or more routing members (for example, the bus bars 32).

In the routing board 31, the plurality of bus bars 32 and the base plate 35 are integrated through insert molding. The routing board 31 is formed as a single member by insert-molding the bus bar 32 with the base plate 35. That is, the bus bar 32 is integrated with the base plate 35 without using a fastening member such as a screw or a bolt. Note that the routing board 31 may be formed by another structure instead of the insert molding.

### (Base Plate)

The base plate 35 is a holding member that integrally holds the plurality of bus bars 32 arranged in the horizontal direction at intervals. The base plate 35 is made of, for example, a synthetic resin and has an insulating property. The base plate 35 electrically insulates the plurality of bus bars 32 from each other. The base plate 35 includes a flat surface portion 36 and a plurality of claw portions 37. The base plate 35 may be referred to as an “insulating substrate”.

The flat surface portion 36 is a portion formed in a plate shape in the base plate 35. The flat surface portion 36 has a plate shape formed in the horizontal direction. The flat surface portion 36 forms a main portion of the base plate 35. The flat surface portion 36 forms a base portion (insulating base portion) of the base plate 35. In the present embodiment, the flat surface portion 36 extends over the entire width in the X direction of the base plate 35 and over the entire width in the Y direction of the base plate 35 excluding four corner portions of the base plate 35. The first electronic component 33 is placed on the flat surface portion 36 from the +Z direction side of the flat surface portion 36. That is, the first electronic component 33 is disposed on the +Z direction side with respect to the flat surface portion 36. The plurality of claw portions 37 are located on the outer periphery of the flat surface portion 36. Each claw portion 37 protrudes from the flat surface portion 36 in the +Z direction.

Each bus bar 32 is a routing member (electrical connection member) included in the routing board 31. Each bus bar 32 is, for example, a routing member for forming at least a part of the energization path electrically connected to the first electronic component 33. Each bus bar 32 may be, for example, a routing member for electrically connecting the first electronic component 33 to a second circuit 40 or an external device of the electrical connection unit 1. The bus bar 32 is made of a metal (for example, copper or a copper alloy) and has conductivity. At least a part of each bus bar 32 is held by the base plate 35. The plurality of bus bars 32 may include, for example, portions disposed on the same plane.

At least a part of each bus bar 32 has a plate shape formed in the horizontal direction. At least a part of each bus bar 32 extends along the flat surface portion 36. In the present embodiment, each bus bar 32 has a plate shape formed in the horizontal direction over the entire length. The bus bar 32 is a member that forms an energization path in the horizontal direction.

### 3. Constitution of Second Structure

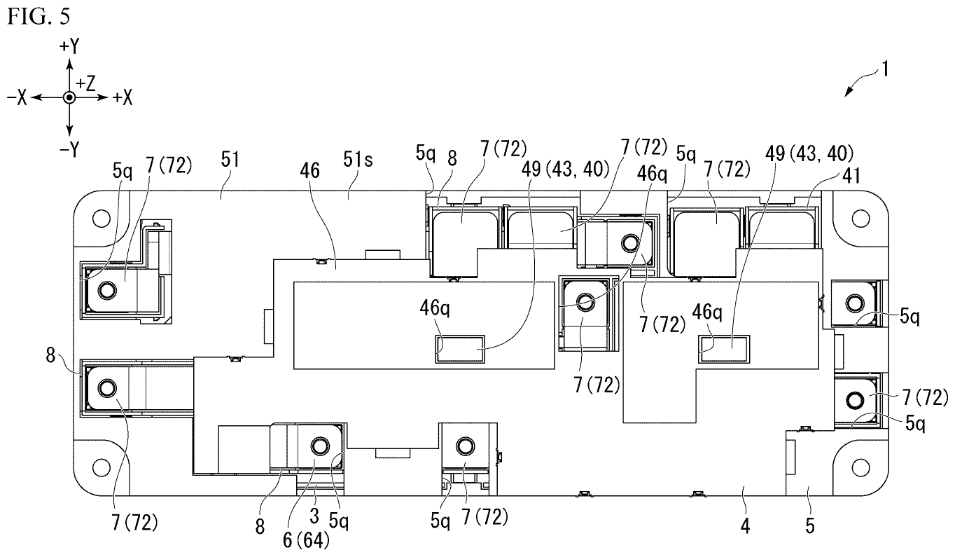

As illustrated in FIGS. 4 to 6, the second structure 4 includes the second circuit 40, a first cover 41, a plurality of lock portions 45, and a second cover 46. The second circuit 40 is supported by the support portion 51. The second circuit 40 includes a plurality of second electronic components 43, and a plurality of bus bars 42.

### (Second Electronic Component)

Each second electronic component 43 is an electronic component for which a degree of freedom in design, component replacement, and the like according to a product to which the electrical connection unit 1 is applied are more likely to be required than the first electronic component 33. The second electronic component 43 may be, for example, an electronic component in which ease of routing is prioritized for each product to which the electrical connection unit 1 is applied, and may be an electronic component in which a component position in the electrical connection unit 1 is likely to vary. The second electronic component 43 may be, for example, an electronic component of which component specification is likely to vary for each product to which the electrical connection unit 1 is applied. The second electronic component 43 may be, for example, an electronic component of which the presence or absence of mounting on the electrical connection unit 1 is likely to vary for different products to which the electrical connection unit 1 is applied. The second electronic component 43 may be, for example, an electronic component that is likely to be replaced due to component deterioration, periodic maintenance, or the like of the electrical connection unit 1.

The second electronic component 43 may be, for example, various sensors (for example, a current sensor or a voltage sensor), a fuse, or a control circuit (for example, a micro controller unit (MCU), a microprocessor unit (MPU), or the like). The second electronic component 43 may be, for example, a relay other than a relay that controls conduction and disconnection of the largest current among a plurality of relays mounted on the electrical connection unit 1. Each of the plurality of second electronic components 43 is electrically connected to at least one bus bar 42 among the plurality of bus bars 42. The second electronic component 43 may include a signal connector 49.

The signal connector 49 is a connector through which a signal related to the second electronic component 43 can be input and output. For example, when the second electronic component 43 is a current sensor, the signal connector 49 may be able to transmit a detection signal related to the current flowing through the second electronic component 43 to the outside of the electrical connection unit 1. For example, when the second electronic component 43 is a fuse, the signal connector 49 may be able to transmit an alarm signal for informing the fusing of the second electronic component 43 to the outside of the electrical connection unit 1. For example, when the second electronic component 43 is a relay, the signal connector 49 may be able to receive a control signal for conduction and disconnection of the second electronic component 43 from the outside of the electrical connection unit 1.

Each bus bar 42 is a routing member for forming an energization path in the second circuit 40. Each bus bar 42 may form, for example, an energization path connected to the second electronic component 43. At least a part of each bus bar 42 extends in the horizontal direction. The bus bar 42 is made of a metal (for example, copper or a copper alloy) and has conductivity. An end portion of each bus bar 42 may be connected to a terminal of the second electronic component 43, the relay bus bar 6, or another bus bar 42 by being fastened with a fastening member such as a screw or a bolt.

### (First Cover and Second Cover)

Each of the first cover 41 and the second cover 46 has a tray shape in which most (excluding a part) of the outer periphery is erected. The first cover 41 and the second cover 46 are combined such that the directions in which the outer peripheries are erected face each other. The first cover 41 has a plurality of openings 41q. The first cover 41 covers the second circuit 40 from a side in the −Z direction in a portion excluding the plurality of openings 41q. The second cover 46 has a plurality of openings 46q. The second cover 46 covers the second circuit 40 from a side in the +Z direction in a portion excluding the plurality of openings 46q. The first cover 41 and the second cover 46 are combined to accommodate most of the second circuit 40 (for example, a portion of the bus bars 42 excluding a portion to be fastened to the relay bus bar 6 and the signal connector 49). For example, each of the first cover 41 and the second cover 46 may be separated from or in contact with the plurality of bus bars 42 and the plurality of second electronic components 43. The second cover 46 is made of, for example, a synthetic resin and has an insulating property.

The first cover 41 is an example of a “second holding member” that holds at least one of the external connection bus bars 7 which will be described below. The structure of the first cover 41 as the second holding member will be described in detail below.

### (Lock Portion)

The plurality of lock portions 45 are located at ends of the second structure 4 on sides in the +X direction, the −X direction, the +Y direction, and the −Y direction. The plurality of lock portions 45 are integrally formed with the second cover 46. The lock portion 45 may be, for example, a snap-fit. The second structure 4 is fixed to the support portion 51 by the plurality of lock portions 45. Each lock portion 45 extends from the outer peripheral upper portion of the first cover 41 toward a first engagement portion 53.

Each lock portion 45 includes an arm portion 45AR and a protrusion 45PR. The arm portion 45AR extends toward the first engagement portion 53 which will be described below. The arm portion 45AR extends from the outer peripheral upper portion of the first cover 41 toward the first engagement portion 53. The arm portion 45AR is deformable so as to warp in the horizontal direction from a posture extending in the Z direction. The arm portion 45AR has a restoring force in a direction opposite to the deformation direction. The protrusion 45PR protrudes from the arm portion 45AR toward the first engagement portion 53 in a direction intersecting the extending direction of the arm portion 45AR.

### 4. Constitution of Metal Base

The metal base 5 includes the support portion 51, a peripheral wall 52, a plurality of the first engagement portions 53, and a plurality of second engagement portions 54. The metal base 5 has a plurality of openings 5q. Each opening 5q is open from the outside of the electrical connection unit 1 to an accommodation space U (see FIG. 2) which will be described below. The metal base 5 covers the first structure 3 from a side in the +Z direction excluding the plurality of openings 5q. At least a part of the metal base 5 is made of a metal (for example, made of aluminum or aluminum alloy). The support portion 51, the peripheral wall 52, and the first engagement portion 53 may be integrally formed using, for example, a metal material. The metal base 5 is also a heat radiation member. Since the metal base 5 is made of a metal, the metal base 5 has a high thermal conductivity, and the metal base 5 easily releases heat inside the metal base 5 to the outside. Also, the opening 5q which will be described below is formed in the metal base 5, and the metal base 5 is designed to have a shape in which internal heat is easily released to the outside through the opening 5q.

### (Support Portion)

The support portion 51 supports the second structure 4 from a side in the −Z direction. The first circuit 30 is disposed on the −Z direction side with respect to the support portion 51. The second circuit 40 is disposed on the +Z direction side with respect to the support portion 51. The support portion 51 is interposed between the first circuit 30 and the second circuit 40. The support portion 51 has the support surface 51s facing in the +Z direction. The support surface 51s may be, for example, a flat surface.

### (Peripheral Wall)

The peripheral wall 52 extends in the −Z direction from the outer edge of the support portion 51 to the outer edge of the base plate 35. The peripheral wall 52 closes the outer periphery of a space sandwiched between the support portion 51 and the base plate 35 in a portion excluding the plurality of openings 5q and the plurality of second engagement portions 54. The peripheral wall 52 covers at least the plurality of first electronic components 33 from sides in the +X direction, the −X direction, the +Y direction, and the −Y direction. With such a constitution, the plurality of first electronic components 33 are accommodated in the accommodation space U (see FIG. 2) defined by the metal base 5 and the routing board 31.

### (Engagement Portion)

Each first engagement portion 53 protrudes from the support portion 51 in the +Z direction. The first engagement portion 53 has a recess 53RS. The recess 53RS is defined by being surrounded by an edge of the first engagement portion 53 protruding in the horizontal direction. The recess 53RS is recessed in a direction in which the protrusion 45PR extends from the arm portion 45AR. When the first cover 41 is brought closer to the support portion 51 in the −Z direction, the protrusion 45PR climbs over the edge of the first engagement portion 53 around the recess 53RS and is fitted into the recess 53RS. Due to such engagement between the first engagement portion 53 and the lock portion 45, the second structure 4 is maintained in a state of being attached to the metal base 5.

Each second engagement portion 54 is located closer to the −Z direction side of the peripheral wall 52. Each second engagement portion 54 is caught by the tip end of the related claw portion 37. By this catch, the metal base 5 holds the base plate 35. The second engagement portion 54 may be, for example, an opening that opens the peripheral wall 52 in the horizontal direction. Each second engagement portion 54 is not limited to the opening, and may be a recess recessed from the inner peripheral surface of the peripheral wall 52. On the other hand, each claw portion 37 may have any lock structure as long as it can be hooked onto the related second engagement portion 54.

### (Opening)

Among the plurality of openings 5q, the opening 5q related to the relay bus bar 6 is disposed at a position where the first circuit 30 and the second circuit 40 can be electrically connected. The opening 5q related to the relay bus bar 6 may be disposed, for example, at a position where the relay bus bar 6 is exposed from the metal base 5 in the +Z direction. Among the plurality of openings 5q, the opening 5q related to the external connection bus bar 7 is disposed at a position where the external connection bus bar 7 can pass between the −Z direction side of the support portion 51 and the +Z direction side of the support portion 51.

### 5. Constitution of Relay Bus Bar

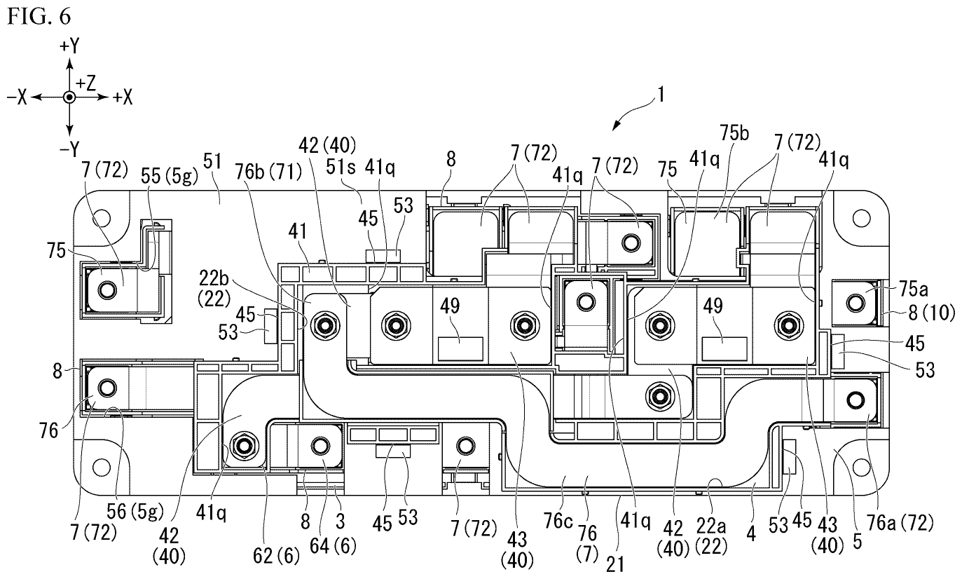

The relay bus bar 6 is electrically connected to the bus bar 32 and the bus bar 42 so as to relay the bus bar 32 and the bus bar 42. The relay bus bar 6 is a member that forms an energization path in the vertical direction. The relay bus bar 6 includes connection portions 61 and 62 and an extension portion 63. The connection portion 61 is electrically connected to the bus bar 32, for example. Two connection portions 61 are provided. For example, one of the two connection portions 61 may be fastened to one end of the bus bar 32 with a fastening member such as a screw or a bolt in an energizable manner. For example, the other of the two connection portions 61 may be fastened to one end of a routing member (for example, a bus bar) extending from a device outside the electrical connection unit 1 with a fastening member such as a screw or a bolt in an energizable manner to each other. The connection portion 62 is disposed on the +Z direction side with respect to the connection portion 61. The connection portion 62 is electrically connected to the bus bar 42, for example (see FIG. 6). For example, the connection portion 62 may be fastened to one end of the bus bar 42 with a fastening member such as a screw or a bolt in an energizable manner. The extension portion 63 extends over the connection portion 61 and the connection portion 62. The extension portion 63 is provided between the connection portion 61 and the connection portion 62. The extension portion 63 connects the connection portion 61 to the connection portion 62.

### 6. Constitution of External Connection Bus Bar

The plurality of external connection bus bars 7 are bus bars for electrically connecting an external device to the first circuit 30 or the second circuit 40. Each external connection bus bar 7 includes connection portions 71 and 72 and an extension portion 73. The connection portion 71 is electrically connected to the bus bar 32 or the bus bar 42. For example, the connection portion 71 may be fastened to one end of the bus bar 32 or the bus bar 42 with a fastening member such as a screw or a bolt in an energizable manner. In at least one external connection bus bar 7 of the external connection bus bars 7, the connection portion 71 may be disposed, for example, on the +Z direction side with respect to the support surface 51s (see FIG. 4). The connection portion 72 can be electrically connected to a routing member (for example, a bus bar) extending from an external device. The connection portion 72 is disposed on the +Z direction side or the −Z direction side with respect to the connection portion 71. In at least some external connection bus bars 7 of the external connection bus bars 7, the connection portion 72 may be disposed, for example, on the +Z direction side with respect to the support surface 51s (see FIG. 4). Some of the connection portions 72 may be fastened to a routing member (for example, a bus bar) extending from an external device with a fastening member such as a screw or a bolt, for example. Some of the connection portions 72 may be connected to a routing member (for example, a bus bar) extending from an external device by welding, for example. The extension portion 73 extends over the connection portion 71 and the connection portion 72. The extension portion 73 is provided between the connection portion 71 and the connection portion 72. The extension portion 73 connects the connection portion 71 to the connection portion 72.

### 7. Constitution of Auxiliary Base Member

The plurality of auxiliary base members 8 are support members that assist three-dimensional routing of various bus bars. Each of the plurality of auxiliary base members 8 supports the relay bus bar 6 or the external connection bus bar 7 from the −Z direction side. The auxiliary base member 8 may support, for example, two external connection bus bars 7. The auxiliary base member 8 is disposed between the routing board 31 and the related bus bar among the relay bus bar 6 and the external connection bus bar 7 in the Z direction.

Some of the plurality of auxiliary base members 8 hold end portions for external connection of the two external connection bus bars 7. Such an auxiliary base member 8 is hereinafter referred to as a first holding member 10. The first holding member 10 and a peripheral structure of the first holding member 10 will be described in detail below.

### 8. Constitution of Insulating Sheet

A plurality of insulating sheets 91 are insulating members for insulating the first circuit 30 and the second circuit 40. As illustrated in FIG. 2, each insulating sheet 91 has a sheet shape formed in the horizontal direction. Each insulating sheet 91 has an insulating property. Each insulating sheet 91 is made of, for example, a synthetic resin such as polyester or polyimide. The plurality of insulating sheets 91 include a first insulating sheet 91A and a pair of second insulating sheets 91B.

The first insulating sheet 91A is disposed on the −Z direction side of the first circuit 30. For example, the first insulating sheet 91A is disposed so as to be in contact with a surface on the −Z direction side of the routing board 31. The first insulating sheet 91A may be disposed, for example, between the routing board 31 and a pair of first heat transfer members 92A which will be described below.

As illustrated in FIG. 4, the pair of second insulating sheets 91B are disposed on the −Z direction side of the second circuit 40. The pair of second insulating sheets 91B faces the support surface 51s, for example. The pair of second insulating sheets 91B are disposed so as to be in contact with the support surface 51s, for example. Each second insulating sheet 91B may be disposed, for example, between the support surface 51s and a pair of related second heat transfer members 92B among two pairs of second heat transfer members 92B which will be described below.

### 9. Constitution of Heat Transfer Member

A plurality of heat transfer members 92 are members for transferring heat (Joule heat) generated by the first circuit 30 and the second circuit 40 at the time of energization to the outside of the first circuit 30 and the second circuit 40. Each heat transfer member 92 is, for example, a heat transfer sheet (for example, a thermally conductive silicone sheet) having elasticity. Each heat transfer member 92 may be made of, for example, a material having higher thermal conductivity than the base plate 35. However, each heat transfer member 92 is not limited to the above example, and may be a heat transfer member made of a thermally conductive gel or another material. As illustrated in FIG. 2, the plurality of heat transfer members 92 include the pair of first heat transfer members 92A and the two pairs of second heat transfer members 92B.

The pair of first heat transfer members 92A is disposed between the cooling surface (see FIG. 1) of the external cooler 98 and the first insulating sheet 91A. For example, each first heat transfer member 92A may be disposed at a position overlapping the related first electronic component 33 when viewed in the Z direction.

As illustrated in FIG. 4, the two pairs of second heat transfer members 92B are disposed between the pair of second insulating sheets 91B and the second circuit 40. Each pair of the two pairs of second heat transfer members 92B faces a surface of the related second insulating sheet 91B which faces in the +Z direction. Each pair of the two pairs of second heat transfer members 92B faces a surface of the related second electronic component 43 which faces in the −Z direction. Each pair of second heat transfer members 92B may be disposed at a position overlapping the related second electronic component 43 when viewed in the Z direction. For example, each second electronic component 43 may be placed on the support portion 51 via the bus bar 42 or the external connection bus bar 7, the second heat transfer members 92B, and the second insulating sheet 91B.

### 10. First Holding Member, First Cover, and Peripheral Structure Thereof

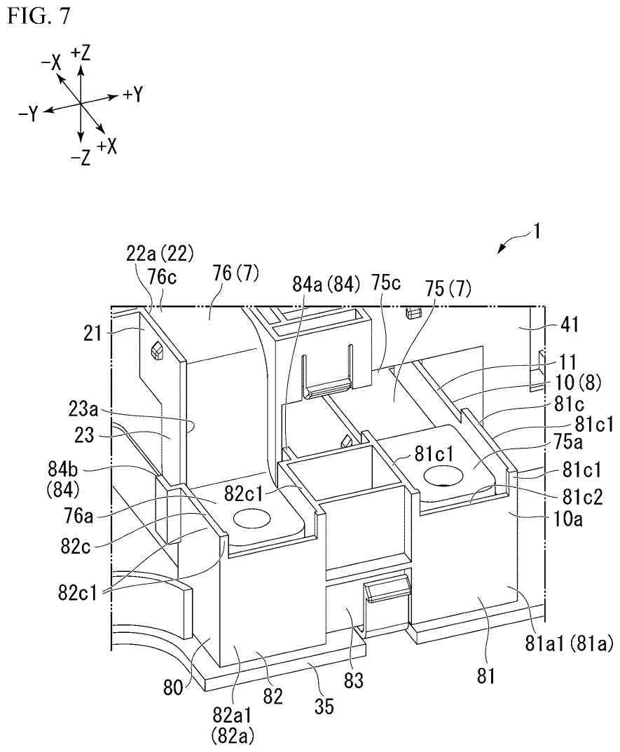

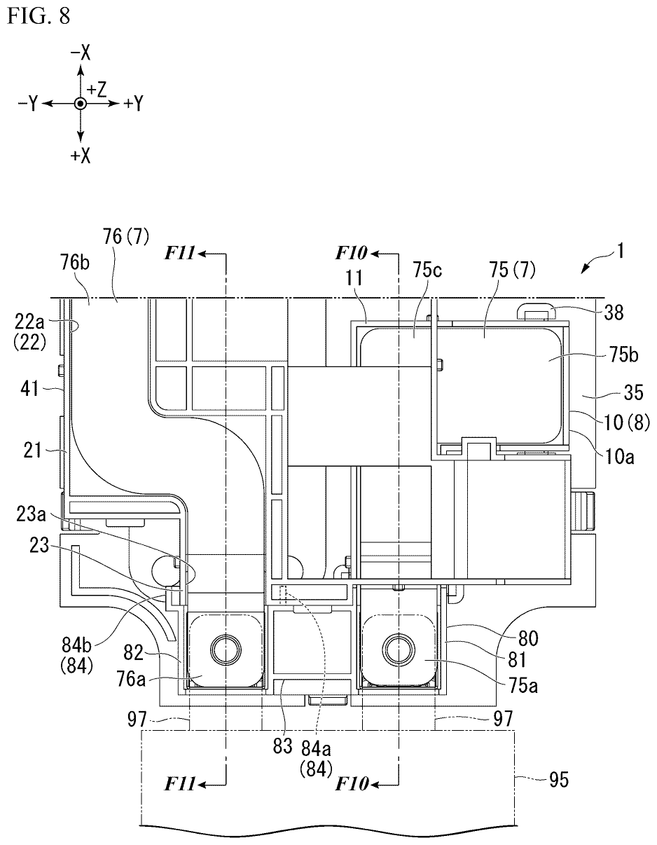

In the present embodiment, as illustrated in FIGS. 7 and 8, the first holding member 10 is one of the plurality of auxiliary base members 8 described above. In the illustrated example, the first holding member 10 is provided at the end portion on the +X direction side of the electrical connection unit 1. The first cover 41 is an example of a “second holding member”. The first holding member 10 and the first cover 41 are members that hold at least one external connection bus bar 7 among the plurality of external connection bus bars 7. Hereinafter, the constitution of the first holding member 10 and the constitution of the first cover 41 as the “second holding member” will be described. The external connection bus bar 7 held by the first holding member 10 is referred to as a first bus bar 75. The external connection bus bar 7 held by the first cover 41 is referred to as a second bus bar 76.

### (First Bus Bar)

The first bus bar 75 is an example of a “first routing member”. The first bus bar 75 is formed in, for example, an L shape. The first bus bar 75 has a first end portion 75a, a third end portion 75b, and a first extension portion 75c. The first end portion 75a is electrically connected to a first external unit 95. The first external unit 95 is a type of an external device that is a connection destination of the electrical connection unit 1. That is, the first external unit 95 may include a battery pack, a load, a charger, and the like.

The third end portion 75b is an end portion located on a side opposite to the first end portion 75a of the first bus bar 75. Both the first end portion 75a and the third end portion 75b are formed in a flat plate shape extending in the horizontal direction. That is, a thickness direction of the first end portion 75a and the third end portion 75b coincides with the Z direction. The first extension portion 75c extends from the first end portion 75a and connects the first end portion 75a and the third end portion 75b. In the present embodiment, the first extension portion 75c is formed so as to extend in the horizontal direction. The shape of the first extension portion 75c extending in the horizontal direction also includes a case where the position of the first extension portion 75c in the Z direction changes from the first end portion 75a to the third end portion 75b. The first extension portion 75c is formed in an L shape. The first extension portion 75c has a first portion 75c1 extending in the −X direction from the first end portion 75a and a second portion 75c2 extending in the −Y direction from the third end portion 75b.

### (Second Bus Bar)

The second bus bar 76 is an example of a “second routing member”. The second bus bar 76 has a second end portion 76a, a fourth end portion 76b (see FIG. 6), and a second extension portion 76c. The second end portion 76a of the second bus bar 76 is connected to the first external unit 95 together with the first end portion 75a of the first bus bar 75. The first end portion 75a of the first bus bar 75 and the second end portion 76a of the second bus bar 76 are adjacent to each other in the Y direction. One of the first end portion 75a of the first bus bar 75 and the second end portion 76a of the second bus bar 76 is a positive electrode terminal electrically connected to the first external unit 95. The other of the first end portion 75a of the first bus bar 75 and the second end portion 76a of the second bus bar 76 is a negative electrode terminal electrically connected to the first external unit 95.

The fourth end portion 76b is an end portion located on a side opposite to the second end portion 76a of the second bus bar 76. Both the second end portion 76a and the fourth end portion 76b are formed in a flat plate shape extending in the horizontal direction. That is, a thickness direction of the second end portion 76a and the fourth end portion 76b coincides with the Z direction. The second extension portion 76c extends from the second end portion 76a and connects the second end portion 76a and the fourth end portion 76b. The second extension portion 76c is disposed at a position different from the first extension portion 75c in the Z direction (on the +Z direction side with respect to the first extension portion 75c). In the present embodiment, the second extension portion 76c is formed so as to extend in the horizontal direction. The shape of the second extension portion 76c extending in the horizontal direction also includes a case where the position of the second extension portion 76c in the Z direction changes from the second end portion 76a to the fourth end portion 76b. The second extension portion 76c is formed to be long in the X direction. The shape of the second extension portion 76c that is long in the X direction also includes a case where the position of the second extension portion 76c in the Y direction changes from the second end portion 76a to the fourth end portion 76b.

### (First Cover)

The first cover 41 is formed separately from the first holding member 10. The first cover 41 is made of, for example, a synthetic resin and has an insulating property. The first cover 41 is disposed at a position facing the first holding member 10 in the Z direction. In the present embodiment, the first cover 41 is disposed on the +Z direction side of the first holding member 10, that is, above the first holding member 10. The first cover 41 is fixed to the support portion 51 of the metal base 5 by engagement between the lock portion 45 and the first engagement portion 53 described above. In addition, the first cover 41 of the present embodiment holds the second extension portion 76c and the fourth end portion 76b. The first cover 41 includes a second main body portion 21 and a lead-out portion 23.

### (Second Main Body Portion)

The second main body portion 21 includes the lock portion 45 and the opening 41q described above. The second main body portion 21 holds at least the second extension portion 76c of the second bus bar 76. In the present embodiment, the second main body portion 21 holds the second extension portion 76c and holds the fourth end portion 76b of the second bus bar 76. The second main body portion 21 may directly hold the fourth end portion 76b, or may hold the fourth end portion 76b with another member (for example, a bus bar, a bolt, or the like) interposed therebetween, for example. The second main body portion 21 extends in the horizontal direction. The shape of the second main body portion 21 extending in the horizontal direction is not limited to a completely flat shape, and may include a case where a fixing structure, a rib, or the like protruding in the Z direction is partially present. The second main body portion 21 is formed to be long in the X direction. A second accommodating chamber 22 in which the second bus bar 76 is accommodated is formed in the second main body portion 21. The second accommodating chamber 22 is open upward. The second accommodating chamber 22 accommodates the second bus bar 76 from the +Z direction side. The second accommodating chamber 22 has a third accommodating chamber 22a and a fourth accommodating chamber 22b (see FIG. 6). The third accommodating chamber 22a has substantially the same shape as the second extension portion 76c of the second bus bar 76 and is formed slightly larger than the second extension portion 76c as viewed in the Z direction. The second extension portion 76c is disposed in the third accommodating chamber 22a. The fourth accommodating chamber 22b is formed at an end portion on the −X direction side of the third accommodating chamber 22a and communicates with the third accommodating chamber 22a. The fourth end portion 76b of the second bus bar 76 is disposed in the fourth accommodating chamber 22b.

### (Lead-Out Portion)

The lead-out portion 23 is a portion that leads out the second end portion 76a of the second bus bar 76 to the outside. In the present embodiment, the lead-out portion 23 is provided at an end portion on the +X direction side of the second main body portion 21. The lead-out portion 23 extends downward from the second main body portion 21. The lead-out portion 23 guides the end portion on the +X direction side of the second extension portion 76c of the second bus bar 76 downward. A lead-out chamber 23a is formed in the lead-out portion 23. The lead-out chamber 23a communicates with the second accommodating chamber 22 of the second main body portion 21 and is open in the +Z direction and the +X direction. The second end portion 76a is led out in the +X direction from the lead-out chamber 23a.

### (First Holding Member)

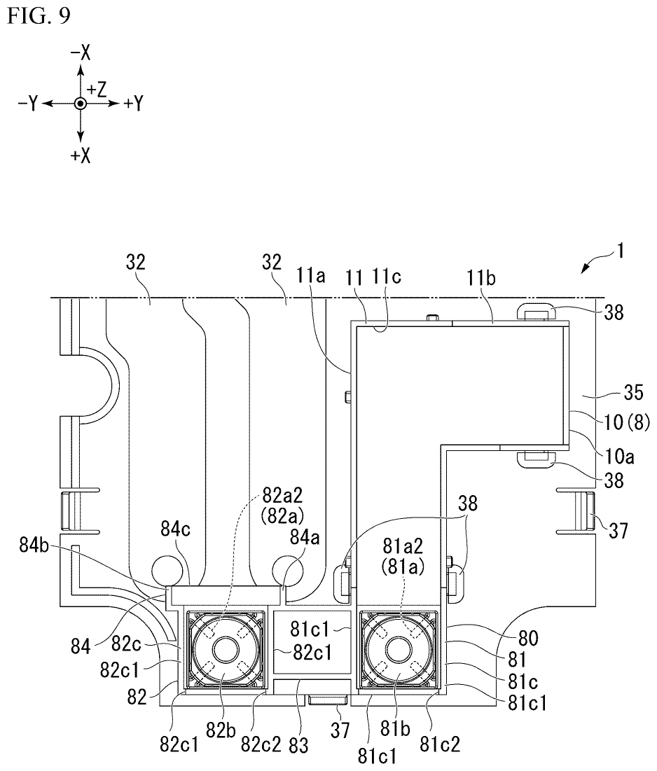

As illustrated in FIGS. 8 and 9, the first holding member 10 holds at least the first extension portion 75c of the first bus bar 75. The first holding member 10 is provided on the base plate 35. The first holding member 10 is regulated from moving in the horizontal direction by a movement regulating portion 38 protruding upward from the base plate 35. Furthermore, the first holding member 10 may be fixed to the base plate 35 by, for example, a fixing portion (not illustrated) (for example, a fastening member such as a bolt, an adhesive, or the like). In addition, the first holding member 10 overlaps at least a part of the first bus bar 75 (in the present embodiment, the entire first bus bar 75) and the second end portion 76a of the second bus bar 76 when viewed in the Z direction (first direction). In addition, the first holding member 10 of the present embodiment holds the first extension portion 75c and the third end portion 75b, and holds the first end portion 75a of the first bus bar 75 and the second end portion 76a of the second bus bar 76. The first holding member 10 includes a first main body portion 11 and a holding portion 80.

### (First Main Body Portion)

The first main body portion 11 is a portion that holds the first extension portion 75c and the third end portion 75b of the first bus bar 75. The first main body portion 11 is formed in an L shape that is the same shape as the first bus bar 75. The first main body portion 11 includes a first portion 11a extending in the X direction and a second portion 11b extending in the +Y direction from an end portion on the −X direction side of the first portion 11a. The first portion 75c1 of the first extension portion 75c of the first bus bar 75 is placed on the first portion 11a. The second portion 75c2 of the first extension portion 75c of the first bus bar 75 and the third end portion 75b of the first bus bar 75 are placed on the second portion 11b. The movement regulating portions 38 are disposed on both sides of the first portion 11a in the Y direction, and another pair of movement regulating portions 38 are disposed on both sides of the second portion 11b in the X direction. In addition, a first accommodating chamber 11c opened to the +Z direction side (upward) is formed in an upper portion of the first main body portion 11. The first extension portion 75c and the third end portion 75b of the first bus bar 75 are accommodated in the first accommodating chamber 11c.

### (Holding Portion)

The holding portion 80 is a portion that holds the first end portion 75a of the first bus bar 75 and the second end portion 76a of the second bus bar 76. The holding portion 80 of the present embodiment holds the first end portion 75a and the second end portion 76a at the same position in the Z direction. The holding portion 80 includes a first holding portion 81, a second holding portion 82, and a coupling portion 83. The first holding portion 81 and the second holding portion 82 are arranged in the Y direction. The first holding portion 81 holds the first end portion 75a of the first bus bar 75. The second holding portion 82 holds the second end portion 76a of the second bus bar 76. The first holding portion 81 is located on the +Y direction side with respect to the second holding portion 82, and the second holding portion 82 is located on the −Y direction side with respect to the first holding portion 81. The coupling portion 83 is provided between the first holding portion 81 and the second holding portion 82. The coupling portion 83 couples the first holding portion 81 and the second holding portion 82 in the Y direction.

### (First Holding Portion)

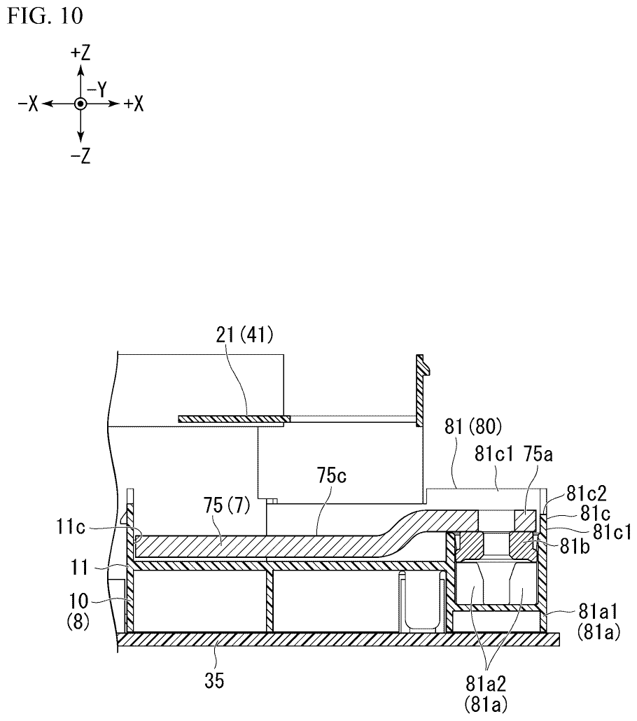

As illustrated in FIG. 10, the first holding portion 81 includes a first support portion 81a, a first fixing portion 81b, and a first wall portion 81c.

### (First Support Portion)

The first support portion 81a extends from the base plate 35 in the +Z direction. The first support portion 81a supports the first fixing portion 81b which will be described below. The first support portion 81a has a first peripheral wall 81a1 and a first leg portion 81a2. The first peripheral wall 81a1 extends from the base plate 35 in the +Z direction. The first peripheral wall 81a1 is formed in a square shape when viewed from the +Z direction side. A plurality of first leg portions 81a2 are provided inside the first peripheral wall 81a1. In the present embodiment, the four first leg portions 81a2 are provided so as to extend from four corner portions of the first peripheral wall 81a1 toward a central portion of the first peripheral wall 81a1 when viewed from the +Z direction side. Each of the first leg portions 81a2 extends in the Z direction.

### (First Fixing Portion)

The first fixing portion 81b is accommodated inside the first peripheral wall 81a1. The first fixing portion 81b is placed on the first leg portion 81a2. The first fixing portion 81b is a member that fixes the first end portion 75a of the first bus bar 75. The upper surface of the first fixing portion 81b is located at the same height as the first peripheral wall 81a1 in the Z direction. The upper surface of the first fixing portion 81b is located on the same horizontal plane as the upper end of the first peripheral wall 81a1. The first end portion 75a is placed on the upper surface of the first fixing portion 81b. The first fixing portion 81b is, for example, a nut that receives a bolt for fastening the first end portion 75a and a terminal 97 of the external device (for example, the terminal 97 of the first external unit 95).

### (First Wall Portion)

The first wall portion 81c extends from the first peripheral wall 81a1 of the first support portion 81a in the +Z direction. The first wall portion 81c is a member that covers the first end portion 75a from sides in at least three directions when viewed in the Z direction. In the present embodiment, the first wall portion 81c has three wall portions 81c1. Each wall portion 81c1 is provided on both sides of the first end portion 75a in the Y direction and on the +X direction side of the first end portion 75a. A first groove 81c2 for leading out the terminal 97 of the external device is formed at the upper end of the wall portion 81c1 on the +X direction side. The lower end of the first groove 81c2 is located at a position lower than that of the upper surface of the first end portion 75a.

(second Holding Portion)

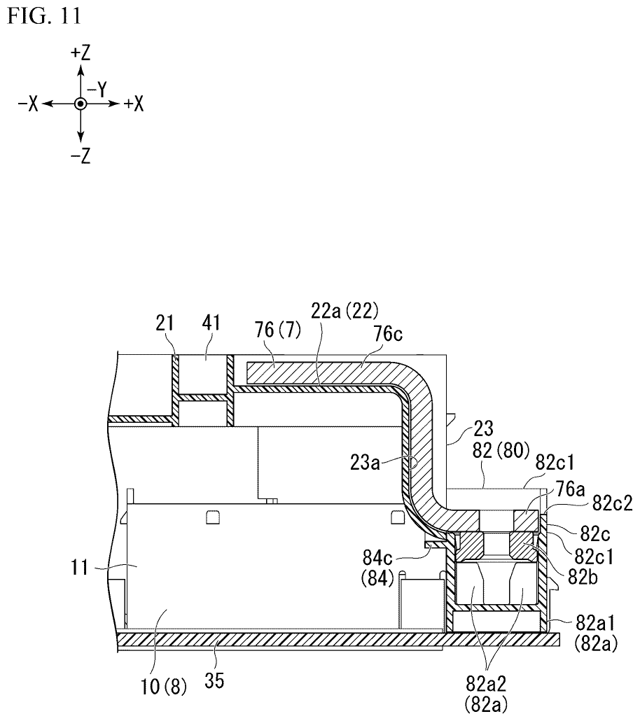

As illustrated in FIG. 11, the second holding portion 82 includes a second support portion 82a, a second fixing portion 82b, a second wall portion 82c, and a receiving portion 84.

### (Second Support Portion)

The second support portion 82a extends from the base plate 35 in the +Z direction.

The second support portion 82a supports the second fixing portion 82b which will be described below. The second support portion 82a has a second peripheral wall 82a1 and a second leg portion 82a2. The second peripheral wall 82a1 extends from the base plate 35 in the +Z direction. The second peripheral wall 82a1 is formed in a square shape when viewed from the +Z direction side. A plurality of second leg portions 82a2 are provided inside the second peripheral wall 82a1. In the present embodiment, the four second leg portions 82a2 are provided so as to extend from four corner portions of the second peripheral wall 82a1 toward a central portion of the second peripheral wall 82a1 when viewed from the +Z direction side. Each of the second leg portions 82a2 extends in the Z direction.

### (Second Fixing Portion)

The second fixing portion 82b is accommodated inside the second peripheral wall 82a1. The second fixing portion 82b is placed on the second leg portion 82a2. The second fixing portion 82b is a member that fixes the second end portion 76a of the second bus bar 76. The upper surface of the second fixing portion 82b is located at the same height as the second peripheral wall 82a1 in the Z direction. The upper surface of the second fixing portion 82b is located on the same horizontal plane as the upper end of the second peripheral wall 82a1. The second end portion 76a is placed on the upper surface of the second fixing portion 82b. The second fixing portion 82b is, for example, a nut that receives a bolt for fastening the second end portion 76a and a terminal 97 of the external device (for example, the terminal 97 of the first external unit 95).

### (Second Wall Portion)

The second wall portion 82c extends from the second peripheral wall 82a1 of the second support portion 82a in the +Z direction. The second wall portion 82c is a member that covers the second end portion 76a from sides in at least three directions when viewed in the Z direction. In the present embodiment, the second wall portion 82c has three wall portions 82c1. Each wall portion 82c1 is provided on both sides of the second end portion 76a in the Y direction and on the +X direction side of the second end portion 76a. A second groove 82c2 for leading out the terminal 97 of the external device is formed at the upper end of the wall portion 82c1 on the +X direction side. The lower end of the second groove 82c2 is located at a position lower than that of the upper surface of the second end portion 76a.

### (Receiving Portion)

The receiving portion 84 is a member that performs alignment between the first holding member 10 and the first cover 41. The receiving portion 84 includes a first regulating portion 84a, a second regulating portion 84b, and a connection portion 84c.

(First Regulating Portion and Second Regulating Portion)

Both the first regulating portion 84a and the second regulating portion 84b are formed at the upper end portion of the second holding portion 82. The first regulating portion 84a and the second regulating portion 84b are disposed so as to face each other in the Y direction, the first regulating portion 84a is disposed on the +Y direction side with respect to the second regulating portion 84b, and the second regulating portion 84b is disposed on the −Y direction side with respect to the first regulating portion 84a. The first regulating portion 84a faces an end portion (lead-out portion 23) of the first cover 41 on the +X direction side from the +Y direction side, and the second regulating portion 84b faces an end portion (lead-out portion 23) of the first cover 41 on the +X direction side from the −Y direction side. In the present embodiment, both the first regulating portion 84a and the second regulating portion 84b are formed so as to extend in the Z direction from the upper end of the second wall portion 82c to the upper end portion of the second support portion 82a. The lower end of the first regulating portion 84a and the lower end of the second regulating portion 84b are connected by the connection portion 84c.

The first main body portion 11, the first support portion 81a, the first wall portion 81c, the second support portion 82a, the second wall portion 82c, the receiving portion 84, and the coupling portion 83 described above are integrally formed and constitute a case portion 10a of the first holding member 10. The case portion 10a is made of a synthetic resin and has an insulating property.

### 11. Advantages

Incidentally, in a case where two routing members (for example, bus bars) for external connection are held by different holding members, the distance between terminals for external connection of the two routing members becomes unstable in some cases.

On the other hand, in the present embodiment, the electrical connection unit 1 is the on-vehicle electrical connection unit 1. The electrical connection unit 1 includes the first bus bar 75 (first routing member), the first holding member 10, the second bus bar 76 (second routing member), and the first cover 41 (second holding member). The first bus bar 75 has the first end portion 75a and the first extension portion 75c. The first end portion 75a is electrically connected to a first external unit 95. The first extension portion 75c extends from the first end portion 75a. The first holding member 10 holds at least the first extension portion 75c of the first bus bar 75. The second bus bar 76 has the second end portion 76a and the second extension portion 76c. The second end portion 76a is electrically connected to the first external unit 95. When the thickness direction of the second end portion 76a is the Z direction (first direction), the second extension portion 76c extends from the second end portion 76a and is disposed at a position different from the first extension portion 75c in the Z direction. The first cover 41 is formed separately from the first holding member 10. The first cover 41 holds at least the second extension portion 76c of the second bus bar 76. The first holding member 10 has the holding portion 80 that holds the first end portion 75a of the first bus bar 75 and the second end portion 76a of the second bus bar 76. According to this constitution, since the first end portion 75a of the first bus bar 75 and the second end portion 76a of the second bus bar 76 are held by one first holding member 10, relative movement between the first end portion 75a and the second end portion 76a is prevented. Therefore, the distance between the first end portion 75a and the second end portion 76a for external connection can be stabilized. That is, component intersection is less likely to occur in the distance between the first end portion 75a and the second end portion 76a.

In the present embodiment, the first end portion 75a and the second end portion 76a are adjacent to each other in the Y direction. The holding portion 80 holds the first end portion 75a and the second end portion 76a at the same position in the Z direction. According to this constitution, the terminal 97 of the first external unit can be easily connected to both the first end portion 75a and the second end portion 76a. Therefore, workability is improved.

In the present embodiment, the first bus bar 75 has the third end portion 75b located on a side opposite to the first end portion 75a. The second bus bar 76 has the fourth end portion 76b located on a side opposite to the second end portion 76a. The first cover 41 holds the second extension portion 76c and the fourth end portion 76b. The first holding member 10 holds the first extension portion 75c and the third end portion 75b, and holds the first end portion 75a of the first bus bar 75 and the second end portion 76a of the second bus bar 76. According to this constitution, the entire first bus bar 75 and the entire second bus bar 76 are stably held.

In the present embodiment, one of the first end portion 75a of the first bus bar 75 and the second end portion 76a of the second bus bar 76 is a positive electrode terminal electrically connected to the first external unit 95. The other of the first end portion 75a of the first bus bar 75 and the second end portion 76a of the second bus bar 76 is a negative electrode terminal electrically connected to the first external unit 95. According to this constitution, the distance between the positive electrode terminal and the negative electrode terminal is stabilized. For this reason, for example, electrical noise is less likely to be mixed.

In the present embodiment, the first holding member 10 overlaps at least a part of the first bus bar 75 and the second end portion 76a of the second bus bar 76 when viewed in the Z direction. According to this constitution, the constituent components of the electrical connection unit 1 are prevented from spreading in the horizontal direction. Therefore, the electrical connection unit 1 is designed to be small.

In the present embodiment, the holding portion 80 has the first regulating portion 84a and the second regulating portion 84b. The first regulating portion 84a faces the end portion of the first cover 41 from the +Y direction side (first side in the second direction). The second regulating portion 84b faces the end portion of the first cover 41 from the −Y direction side opposite to the first regulating portion 84a. According to this constitution, the movement of the first cover 41 in the Y direction with respect to the first holding member 10 is regulated. Therefore, misalignment between the first holding member 10 and the first cover 41 can be prevented, and alignment between the first holding member 10 and the first cover 41 can be easily performed.

In the present embodiment, the holding portion 80 has the first wall portion 81c and the second wall portion 82c. The first wall portion 81c surrounds the first end portion 75a from sides in at least three directions when viewed in the Z direction. The second wall portion 82c surrounds the second end portion 76a from sides in at least three directions when viewed in the Z direction. According to this constitution, misalignment of the first end portion 75a in the horizontal direction is suppressed by the first wall portion 81c, and misalignment of the second end portion 76a in the horizontal direction is suppressed by the second wall portion 82c.

### (Modification Example)

Next, several modification examples will be described. Note that a constitution other than that described below in each modification example is the same as the constitution of the above-described embodiment.

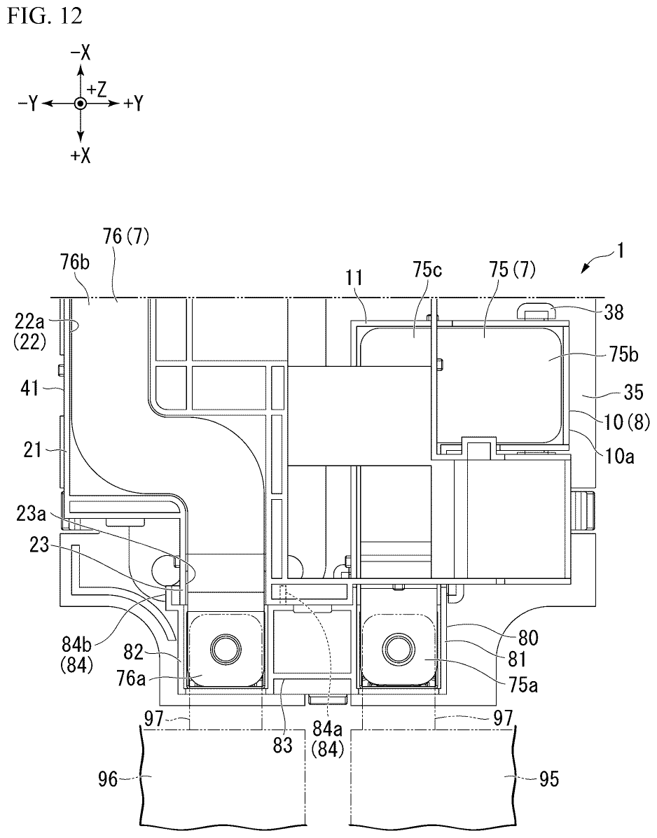

For example, as illustrated in FIG. 12, the second end portion 76a of the second bus bar 76 may be connected to a second external unit 96 different from the first external unit 95 electrically connected to the first end portion 75a of the first bus bar 75. Similarly to the first external unit 95, the second external unit 96 is a type of an external device that is a connection destination of the electrical connection unit 1. That is, the second external unit 96 may include a battery pack, a load, a charger, and the like.

Several embodiments and modification examples have been described above. However, the embodiments and the modification examples are not limited to the examples described above. For example, a plurality of embodiments may be realized in combination with each other.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

### REFERENCE SIGNS LIST

1 Electrical connection unit
3 First structure
4 Second structure
5 Metal base
5q Opening
6 Relay bus bar
7 External connection bus bar
8 Auxiliary base member
10 First holding member
10a Case portion
11 First main body portion
11a First portion
11b Second portion
11c First accommodating chamber
21 Second main body portion
22 Second accommodating chamber
22a Third accommodating chamber
22b Fourth accommodating chamber
23 Lead-out portion
23a Lead-out chamber
30 First circuit
31 Routing board
32 Bus bar
33 First electronic component
34 Connection component
35 Base plate
36 Flat surface portion
37 Claw portion
38 Movement regulating portion
40 Second circuit
41 First cover (second holding member)
41q Opening
42 Bus bar
43 Second electronic component
45 Lock portion
45AR Arm portion
45PR Protrusion
46 Second cover
46q Opening
49 Signal connector
51 Support portion
51s Support surface
52 Peripheral wall
53 First engagement portion
53RS Recess
54 Second engagement portion
61 Connection portion
62 Connection portion
63 Extension portion
71 Connection portion
72 Connection portion
73 Extension portion
75 First bus bar (first routing member)
75a First end portion
75b Third end portion
75c First extension portion
75c1 First portion
75c2 Second portion
76 Second bus bar (second routing member)
76a Second end portion
76b Fourth end portion
76c Second extension portion
80 Holding portion
81 First holding portion
81a First support portion
81a1 First peripheral wall
81a2 First leg portion
81b First fixing portion
81c First wall portion
81c1 Wall portion
81c2 First groove
82 Second holding portion
82a Second support portion
82a1 Second peripheral wall
82a2 Second leg portion
82b Second fixing portion
82c Second wall portion
82c1 Wall portion
82c2 Second groove
83 Coupling portion
84 Receiving portion
84a First regulating portion
84b Second regulating portion
84c Connection portion
91 Insulating sheet
92 Heat transfer member
95 First external unit
96 Second external unit
97 Terminal
98 Cooler

What is claimed is:

1. An electrical connection unit provided on a vehicle, comprising:
a first routing member that has a first end portion electrically connected to a first external unit and a first extension portion extending from the first end portion;
a first holding member that holds at least the first extension portion of the first routing member;
a second routing member that has a second end portion electrically connected to the first external unit or a second external unit and a second extension portion extending from the second end portion and disposed at a position different from the first extension portion in a first direction when a thickness direction of the second end portion is the first direction; and
a second holding member that is formed separately from the first holding member and holds at least the second extension portion of the second routing member,
wherein the first holding member has a holding portion that holds the first end portion of the first routing member and the second end portion of the second routing member.

2. The electrical connection unit according to claim 1, wherein
the first end portion and the second end portion are adjacent to each other in a second direction intersecting the first direction, and
the holding portion holds the first end portion and the second end portion at the same position in the first direction.

3. The electrical connection unit according to claim 1, wherein
the first routing member has a third end portion located on a side opposite to the first end portion,
the second routing member has a fourth end portion located on a side opposite to the second end portion,
the second holding member holds the second extension portion and the fourth end portion, and
the first holding member holds the first extension portion and the third end portion and holds the first end portion of the first routing member and the second end portion of the second routing member.

4. The electrical connection unit according to claim 1, wherein
one of the first end portion of the first routing member and the second end portion of the second routing member is a positive electrode terminal electrically connected to the first external unit, and
the other of the first end portion of the first routing member and the second end portion of the second routing member is a negative electrode terminal electrically connected to the first external unit.

5. The electrical connection unit according to claim 1, wherein
the first holding member overlaps at least a part of the first routing member and the second end portion of the second routing member when viewed in the first direction.

6. The electrical connection unit according to claim 1, wherein
when a direction intersecting the first direction is a second direction,
the holding portion has a first regulating portion that faces an end portion of the second holding member from a first side in the second direction, and a second regulating portion that faces an end portion of the second holding member from a side opposite to the first regulating portion.

7. The electrical connection unit according to claim 1, wherein the holding portion has
a first wall portion that surrounds the first end portion from sides in at least three directions when viewed in the first direction, and
a second wall portion that surrounds the second end portion from sides in at least three directions when viewed in the first direction.
